(19) United States
(12) Patent Application Publication
(10) Pub. No.: US 2009/0078457 A1
(43) Pub. Date: Mar. 26, 2009

(54) ELECTRONIC COMPONENT AND METHOD FOR MANUFACTURING SAME

(75) Inventors: Toshiyuki Atsumi, Osaka (JP); Michio Ohba, Osaka (JP); Koji Shimoyama, Hyogo (JP); Nobuya Matsutani, Osaka (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 12/064,159

(22) PCT Filed: Oct. 4, 2006
(86) PCT No.: PCT/JP2006/319845

§ 371 Date: Feb. 19, 2008

(30) Foreign Application Priority Data
Oct. 14, 2005 (JP) 2005-300019

(51) Int. Cl. H05K 1/11; H01R 43/00

(52) U.S. Cl. 174/262; 29/825

(57) ABSTRACT

A three-dimensional coil pattern, whose internal electrode is connected to external electrodes through a via, is formed within photosensitive resin colored by colorant. This structure allows this electronic component to be lower profile. Cured and colored resin that works as a protecting section of the coil pattern prevents irregular reflection on the internal electrode or the via due to illuminating the component when the component is mounted, so that the component can be handled with more ease.

This application is a U.S. National Phase Application of PCT International Application PCT/JP2006/319845.

### TECHNICAL FIELD

The present invention relates to an electronic component such as a coil component to be used in a variety of electronic devices, and it also relates to a method for manufacturing the same electronic component.

### BACKGROUND ART

Unexamined Japanese Patent Application Publication No. H09-270355 discloses a coil component shown in FIG. 17 as a conventional electronic component. In FIG. 17, coil-like electric wiring 204 is directly formed on substrate 202, and it is protected by molded resin 206. Substrate 202 has external electrodes 208 formed on its both sides, so that both the ends of wiring 204 are coupled to a plurality of external electrodes 208 respectively. The semiconductor technique is thus used on substrate 202 for accurately forming electric wiring 204, so that the electronic component can be downsized. When a coil needs a greater range of characteristics, a narrower coil wiring is used or the wiring is formed on substrate 202 at a higher density in order to increase the number of coil turns (the number of windings).

However, the conventional electronic component is formed of a given wiring formed on a substrate, so that a thickness of the substrate per se becomes a factor influencing a thickness of the electronic component. As a result, it is difficult to design an electronic component having a lower profile.

In the case of increasing the types of coils or broadening the range of coil characteristics, the number of coil turns is increased. In such a case, a more narrowly spaced wiring of the coil is used for forming the coil in a limited place, so that the wiring resistance of the coil increases, which has sometimes adversely affected the characteristics. Three-dimensional pile-up of the wirings of a coil in the thickness direction has necessarily increased the thickness of the product.

### DISCLOSURE OF INVENTION

An electronic component of the present invention comprises the following elements: a protecting section formed of colorant and photosensitive resin; a coil wiring formed within the protecting section and having a via connection; and external electrodes buried in the protecting section while parts of the external electrodes are exposed.

This structure allows the present invention to form a three-dimensional coil wiring without using a substrate, so that the electronic component can be downsized and lowered its height. On top of that, use of colored photosensitive resin for forming the coil wiring allows improving mounting handleability of the component. Resist can be also prevented from remaining at the via connection, thereby improving stability in electrical connection of the coil wiring. As a result, an electronic component with a lower profile and yet having a high Q value is obtainable.

A method for manufacturing the electronic component comprises the steps of:
(a) forming a groove or hole in a given shape by using photo resist colored by colorant;
(b) forming a foundation-electrode at the groove or the hole;
(c) depositing electrical wiring material, whose principal component is copper, on the foundation-electrode;
(d) removing parts of the wiring material for making a surface flat;
(e) repeating the steps of (a) through (d) several times, and
(f) dividing electronic components thus formed into pieces, i.e. discrete components.

The method for manufacturing the electronic component of the present invention uses no substrate, so that an increase in wiring resistance can be suppressed. As a result, an electronic component with a lower profile and excellent in electrical characteristics is obtainable.

### BRIEF DESCRIPTION OF THE DRAWINGS

FIG. 1A shows a sectional view partially illustrating an electronic component in accordance with a first embodiment of the present invention.

FIG. 1B shows an enlarged partial view of the electronic component in accordance with the first embodiment.

FIG. 2A shows a perspective view of a three dimensional structure of internal and external electrodes of the electronic component in accordance with the first embodiment.

FIG. 2B shows a sectional view of a three dimensional structure of the internal electrode and external electrode of the electronic component in accordance with the first embodiment.

FIG. 2C shows a sectional view of a three dimensional structure of the internal electrode and external electrode of the electronic component in accordance with the first embodiment.

FIG. 3 illustrates a method for manufacturing an electronic component in accordance with a second embodiment of the present invention.

FIG. 4A illustrates a method for manufacturing an electronic component in accordance with the second embodiment of the present invention.

FIG. 4B illustrates a method for manufacturing the electronic component in accordance with the second embodiment of the present invention.

FIG. 5A shows a sectional view illustrating a method for manufacturing an electronic component in accordance with a third embodiment of the present invention.

FIG. 5B shows a sectional view illustrating a method for manufacturing the electronic component in accordance with the third embodiment of the present invention.

FIG. 5C shows a sectional view illustrating a method for manufacturing the electronic component in accordance with the third embodiment of the present invention.

FIG. 6A shows a sectional view illustrating a method for manufacturing the electronic component in accordance with the third embodiment of the present invention.

FIG. 6B shows a sectional view illustrating a method for manufacturing the electronic component in accordance with the third embodiment of the present invention.

FIG. 7A shows a sectional view illustrating a method for manufacturing the electronic component in accordance with the third embodiment of the present invention.

FIG. 7B shows a sectional view illustrating a method for manufacturing the electronic component in accordance with the third embodiment of the present invention.

FIG. 8A shows a sectional view illustrating a method for manufacturing an electronic component in accordance with the third embodiment of the present invention.

FIG. 8B shows a sectional view illustrating a method for manufacturing the electronic component in accordance with the third embodiment of the present invention.

FIG. 9 shows a sectional view illustrating a method for manufacturing the electronic component in accordance with the third embodiment of the present invention.

FIG. 10 shows a sectional view illustrating a problem of a via, subjected to exposure, of the electronic component in accordance with the third embodiment of the present invention.

FIG. 11 shows a sectional view illustrating residual resin at the bottom of the via of the electronic component in accordance with the third embodiment of the present invention.

FIG. 12 shows a relation between an amount of residual resin and a thickness of resin of the electronic component in accordance with the third embodiment of the present invention.

FIG. 13A shows a sectional view illustrating a state where use of colored resin reduces reflected light of the electronic component in accordance with the third embodiment of the present invention.

FIG. 13B shows a sectional view illustrating a state after an exposure of the electronic component, which uses colored resin, in accordance with the third embodiment of the present invention.

FIG. 14 shows a relation between an exposure amount and the amount of the residual resin of the electronic component in accordance with the third embodiment of the present invention.

FIG. 15 shows a relation between a film thickness of photosensitive resin and a light transmittance of the electronic component in accordance with a fourth embodiment of the present invention.

FIG. 16 shows a relation between the amount of the residual resin and the thickness of resin of the electronic component in accordance with a fifth embodiment of the present invention.

FIG. 17 shows a perspective view of a conventional coil component.

### DESCRIPTION OF REFERENCE MARKS

100 internal electrode (coil wiring)
102 colored resin (protecting section)
104 external electrode
106, 107 auxiliary line
110 photosensitive resin
114 liquid
116 coloring liquid
118 photosensitive resin liquid
120 colored photosensitive resin liquid
122 substrate
124, 1242 resin pattern
126, 1262 foundation-electrode
128, 1282 metal
130 uncured conventional resin
132 cured conventional resin
134 light
136 mask
138 light blocking section
140 uncured resin
142 cured resin
144 via hole
146 reflected light
148 fogging section
150 uncured colored resin
152 cured colored resin

### DESCRIPTION OF PREFERRED EMBODIMENTS

Exemplary embodiments of the present invention are demonstrated hereinafter with reference to the accompanying drawings.

### Embodiment 1

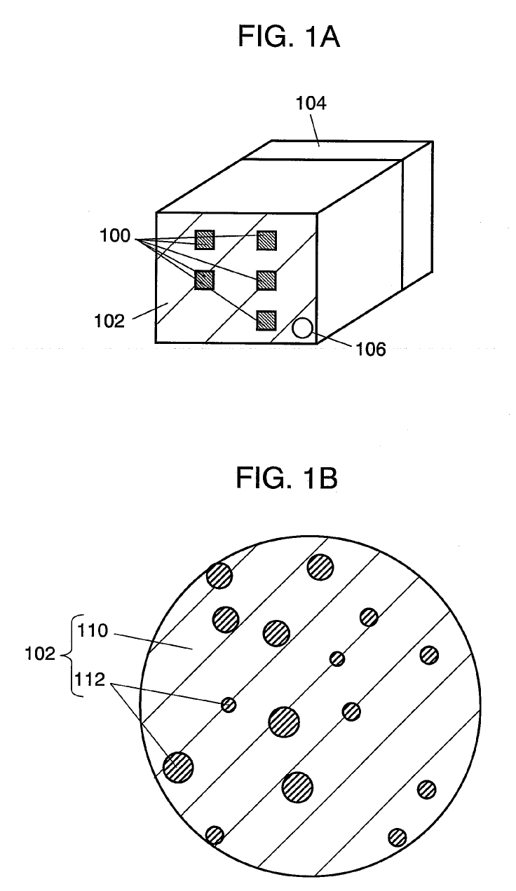

An electronic component in accordance with the first embodiment of the present invention is demonstrated hereinafter with reference to the accompanying drawings. FIG. 1A shows a partial sectional view of the electronic component in accordance with the first embodiment. As shown in FIG. 1A, the electronic component includes internal electrode 100, colored resin section 102, and external electrode 104. FIG. 1B shows an enlarged sectional view of a section circled by auxiliary line 106 shown in FIG. 1A. As shown in FIG. 1A, internal electrode 100 is shaped like a coil having a three-dimensional structure, and built-in colored resin section 102. FIG. 1B shows an enlarged sectional view detailing colored resin section 102. As shown in FIG. 1B, colored resin section 102 is formed of photosensitive resist 110 and colorant 112.

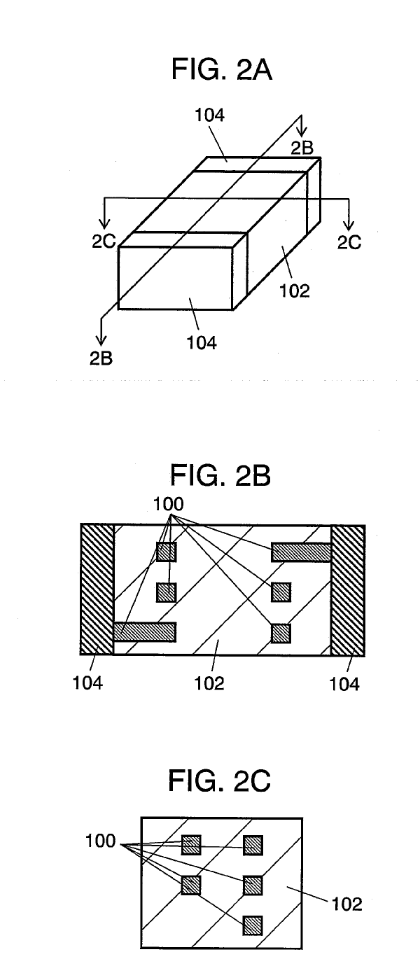

FIG. 2A shows a perspective view illustrating three-dimensional structures of internal electrode 100 and external electrode 104 of the electronic component in accordance with the first embodiment. FIG. 2B is a sectional view cut along line 2B-2B shown in FIG. 2A, and FIG. 2C shows a sectional view cut along line 2C-2C shown in FIG. 2A. As shown in FIGS. 2B and 2C, internal electrode 100 shaped like a coil having a three-dimensional structure is formed by using a via (not shown). To be more specific, internal electrode 100 forms a coil wiring that connects respective external electrodes 104 to each other. Colored resin section 102 is formed of colored photosensitive resin, which can work as a permanent resist for protecting the electronic component per se after exposure and curing. Meanwhile, a negative-type photosensitive resin or photo resist, which can be cured and become unsolvable by light, is preferably used. Because if a positive type, which is decomposed by light, is used, the reliability deserving permanent resist is not obtainable. As shown in FIG. 2A, external electrodes 104 are formed on both the ends of layered unit formed of colored resin section 102. As discussed above, the first embodiment can eliminate a substrate, which a conventional electronic component needs as one of structural elements, so that the electronic component can decrease its height by the thickness of the substrate. As a result, the electronic component in accordance with this first embodiment can contribute to reduction in a height, a weight, and a size of a variety of electronic devices.

Use of colored resin improves the recognition of the electronic component in accordance with the first embodiment. The reason is described hereinafter. For a comparison purpose, a transparent sample having the structure shown in FIGS. 1A and 2A is formed by using nearly transparent resin. Its outer dimension is in accordance with 1005 size of JIS, namely, 1.0 mm×0.5 mm×0.5 mm. Internal electrode 100 and a via (not shown) are formed of copper. The foregoing transparent sample is manufactured in total several tens of thousands. The method of manufacturing is detailed later in the second embodiment or other embodiments.

Then the samples are set in a mounting machine for testing the mountability while video recognition is carried out. The transparent samples sometimes affect the recognition. The investigation finds that the light of an automatic recognition machine reflects upon the surface of metal wiring, e.g. a face, an edge, or a via of the electrical wiring, and the reflected light adversely affects the operation of a layering machine.

The inventors then manufacture samples using the colored resin (hereinafter referred to as a colored sample) in total several tens of thousands. The colored samples are set in the mounting machine for mounting them onto printed circuit boards, and they are tested for mountability while the video recognition is carried out. The test finds almost no problem. A detailed investigation finds that the use of colored resin covering the metal wiring allows preventing the light from reflecting upon the internal electrode. Because when the light reflects upon the surface of inner metal through the colored resin, the light passes through the colored resin twice, i.e. the light makes a round trip, so that the light is weakened. The reflected light due to the internal wiring is not necessarily eliminated completely. For instance, it is not necessarily to use opaque resin through which light cannot pass through at all. To be more specific, use of resin having somewhat tint or light absorption, in other words, use of resin having somewhat colorability, produces no influence of the light reflected from the internal wiring. Because the mounting machine can deal with the reflected light in any way provided that a reflected light can be suppressed under a given level.

If the surface of internal electrode 100 of the coil is roughened in order to prevent the reflected light, this preparation sometimes adversely affects the high-frequency characteristics of the coil. It is thus preferable to smoothen the surface of internal electrode 100 and a via. As the electronic component is further downsized, a thickness of the colored resin layer becomes relatively thinner, so that the possibility for internal reflection to arrive at an contour of the component becomes greater, so that this first embodiment produces greater effect as the electronic component becomes smaller.

The electronic component in accordance with the first embodiment thus comprises the following elements:
a protecting section formed of photosensitive resin where at least a part thereof is colored;
a coil wiring formed in the protecting section and having a via connection; and
external electrodes buried in the protecting section and parts of which are exposed.

This structure allows the electronic component to eliminate a substrate from the structural elements, so that the electronic component can decrease its height, size, and weight. The coil wiring is sealed in the colored resin, thereby preventing an adverse affect to the recognition done by the video recognition accompanying the operation of the automatic mounting machine. The adverse affect is produced by the light reflected on the metal surface of a coil-like wiring, a corner of the wiring, or a via.

### Embodiment 2

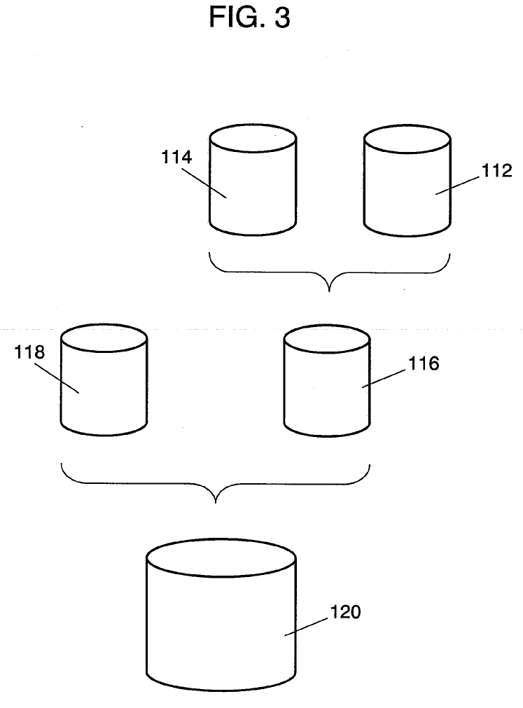

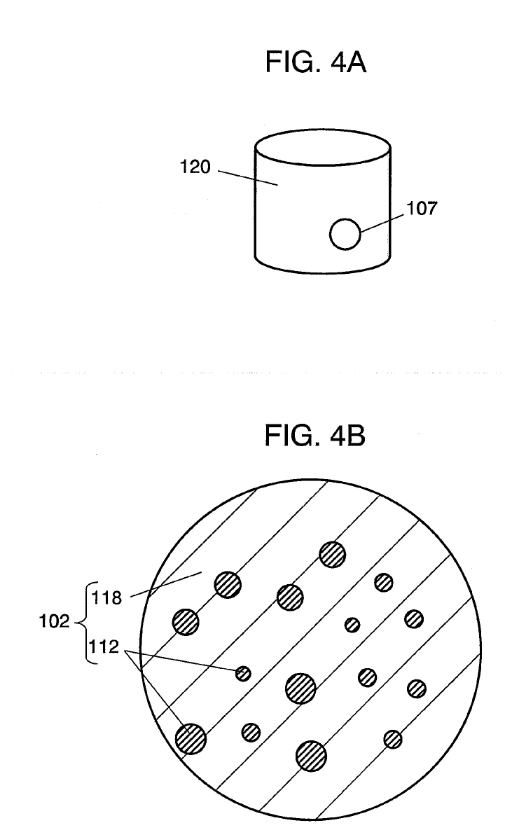

An electronic component in accordance with the second embodiment of the present invention is demonstrated with reference to the accompanying drawings. This second embodiment details the coloring of photosensitive resin. FIGS. 3, 4A and 4B illustrate a method for manufacturing the electronic component in accordance with the second embodiment.

FIG. 3 shows that colored photosensitive resin liquid 120 is formed of colorant 112, liquid 114, coloring liquid 116, and photosensitive resin liquid 118. As shown in FIG. 3, firstly, add colorant 112 to liquid 114 for forming coloring liquid 116, then this mix coloring liquid 116 and photosensitive resin liquid 118 together for forming colored photosensitive resin liquid 120.

Pigment, die, or carbon-oriented material commercially available can be used as colorant 112. These materials are dispersed into liquid 114 by a bead mill. The pigment dispersed into liquid 114, e.g. colored ink to be used in ink jet devices, can be used as colorant 116. Liquid 114 is preferably selected from organic solvent, mutually soluble with the photosensitive resin, to be used for, e.g. diluting photosensitive resin 118.

FIGS. 4A and 4B illustrate a method for manufacturing the electronic component in accordance with the second embodiment of the present invention, and detail the colored photosensitive resin liquid completed. FIG. 4B shows an enlarged sectional view of a section circled with auxiliary line 107 in FIG. 4A. As FIG. 4B tells, colored photosensitive resin liquid 120 contains colorant 112 uniformly dispersed or solved in photosensitive resin liquid 118.

### Embodiment 3

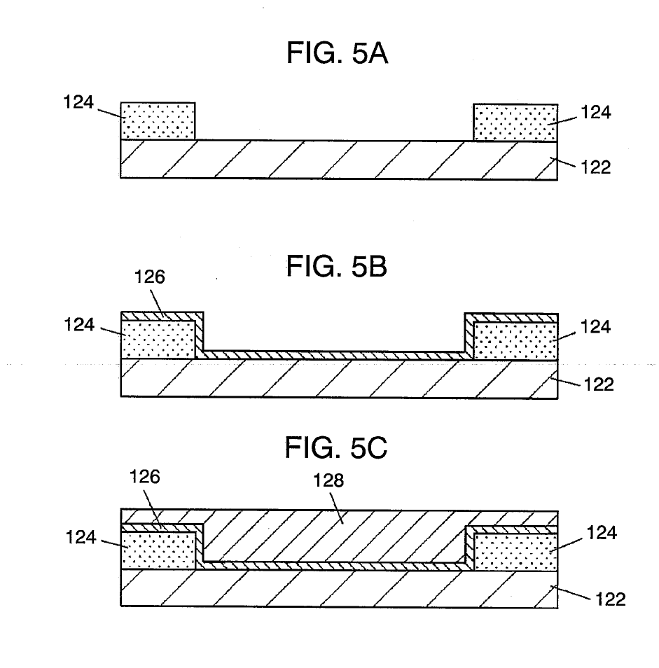

Embodiment 3 refers to the manufacturing of the electronic component using the colored photosensitive resin with reference to the accompanying drawings. FIG. 5A through FIG. 9 shows sectional views illustrating a method for manufacturing an electronic component in accordance with the third embodiment of the present invention. As shown in FIGS. 5A, 5B and 5C, the electronic component is formed of substrate 122, resin pattern 124, foundation-electrode 126, and metal 128. As shown in FIG. 5A, firstly, form the resin pattern 124 on substrate 122, then as shown in FIG. 5B, form the foundation-electrode 126 on resin pattern 124. Either one of a plating method (electroless plating) or a thin film method (sputtering) can be selected for forming foundation-electrode 126, so that foundation-electrode 126 inexpensive and excellent in adhesiveness is obtainable. Then as shown in FIG. 5C, form the metal 128 such that it covers foundation-electrode 126. Metal 128 working as the wiring is formed by deposition of wiring material, and can be made by an electro-plating method which uses the adhesiveness and electrical conductivity of foundation-electrode 126. Metal 128 is thus formed thickly.

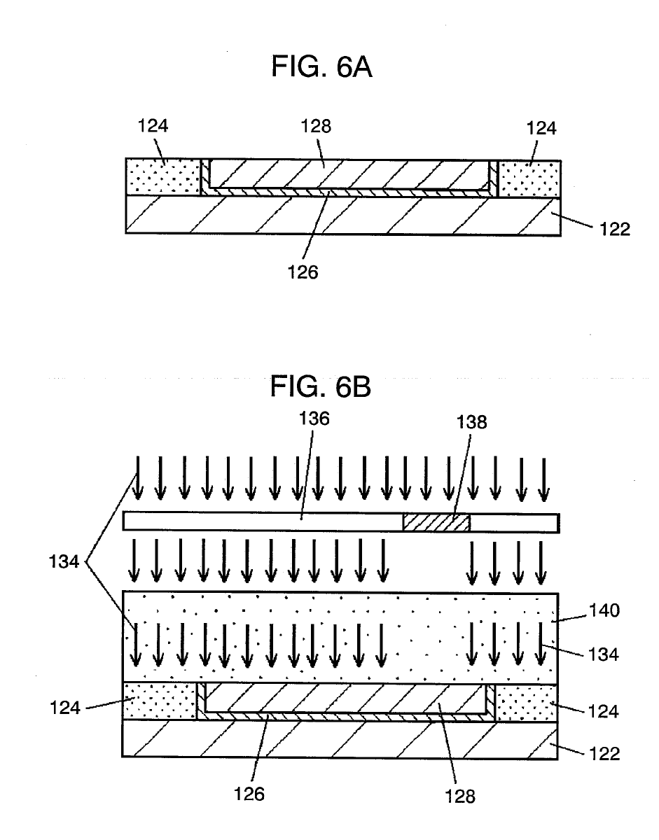

Next, remove unnecessary portion of metal 128, and obtain a shape shown in FIG. 6A. At the same time, resin pattern 124 and foundation-electrode 126 can be partially removed besides metal 128. An etching method or a cutting method can be used for this removal. Then as shown in FIG. 6B, apply the photosensitive resin to the state shown in FIG. 6A.

As FIG. 6B tells, uncured resin 140 is formed on the electronic component, and light 134 is shot to uncured resin 140 through mask 136 having light blocking section 138. The unnecessary portion of metal 128 has been removed from the surface of metal 128 as shown in FIG. 6B, and uncured photosensitive resin liquid is thickly applied on that surface, and the resin liquid is dried for forming uncured resin 140. Then an exposure machine (not shown) shoots light 134 to uncured resin 140 through mask 136 for selectively curing the resin. On the other hand, uncured resin 140 placed under light blocking section 138 of mask 136 remains uncured. Then develop the electronic component with predetermined developing solution, thereby removing only the uncured portion of the resin.

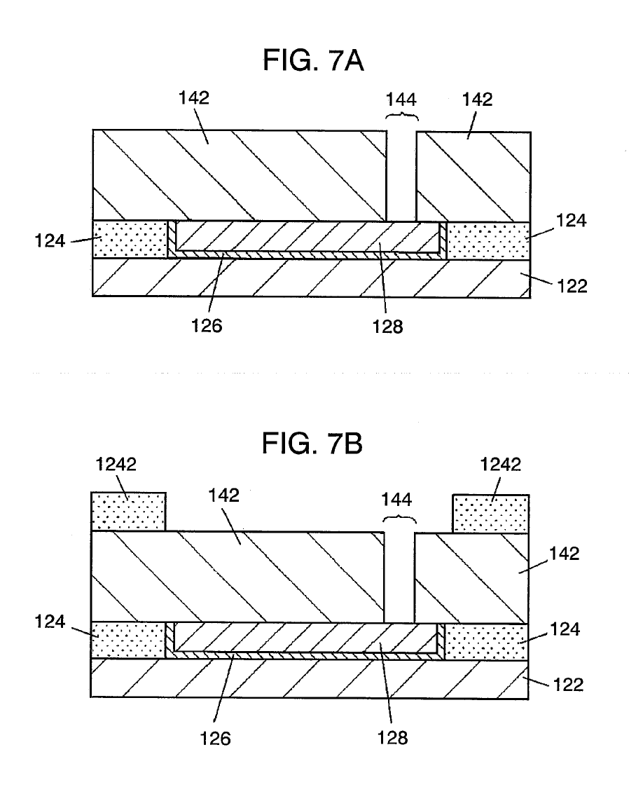

The state shown in FIG. 7A is thus obtained. As shown in FIG. 7A, the electronic component includes cured resin 142 having via hole 144. Cured resin 142 is formed by curing the uncured resin 140 having photo-curing properties. In FIG. 7A, light blocking section 138 of mask 136 remains as via-hole 144, and the section having undergone the exposure becomes cured resin 142. Then form a resin pattern 1242 as shown in FIG. 7B.

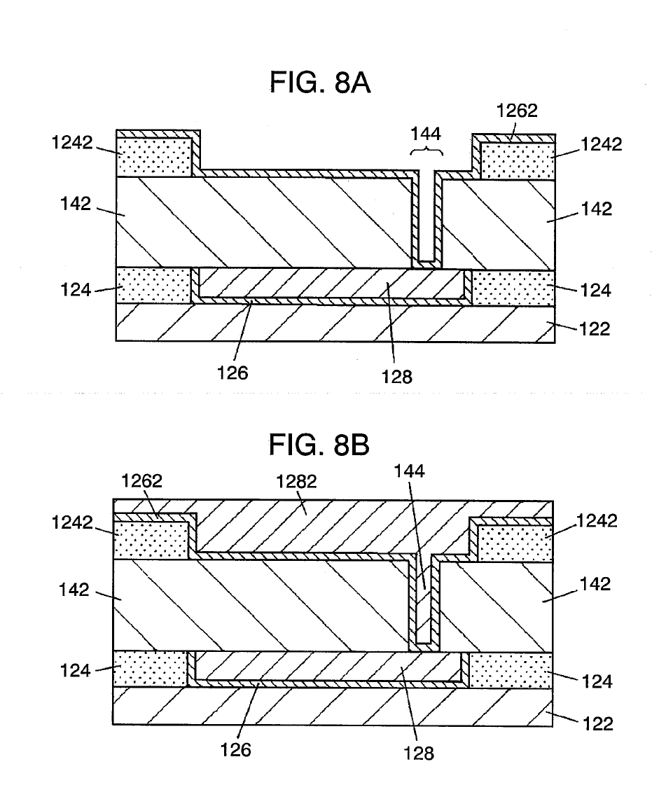

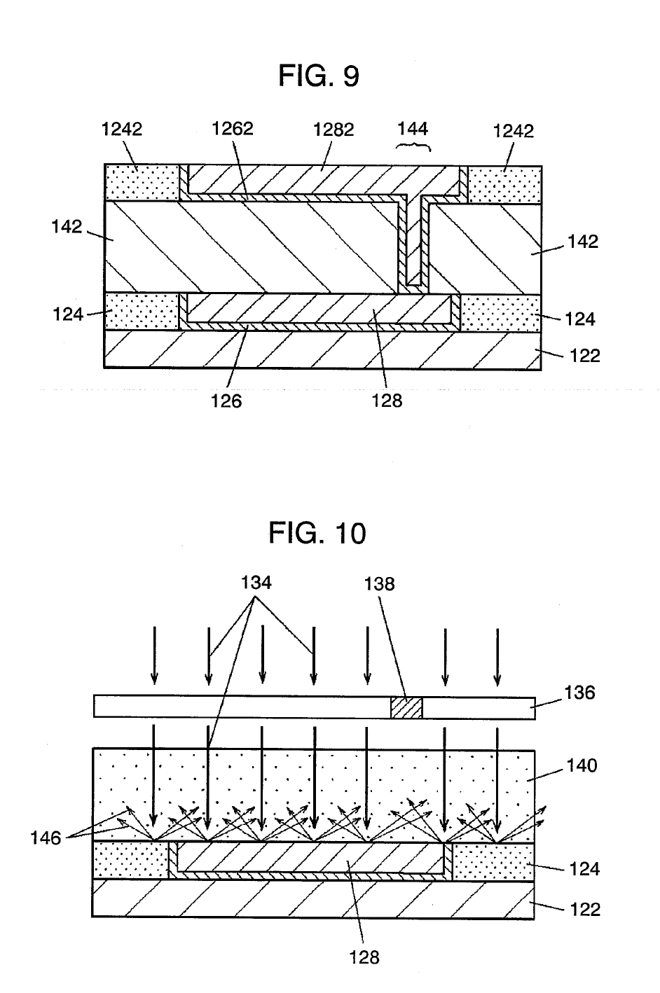

Then as shown in FIG. 8A, form additional electrode-undeplate 1262, and as shown in FIG. 8B, form metal 1282. Remove unnecessary portion of metal 1282 as shown in FIG. 9. Repeat the steps demonstrated in FIG. 5A-FIG. 9 several times, and remove the substrate 122 before the electronic components in the manufacturing steps are divided into pieces, i.e. discrete components. A large number of the electronic components, shown in FIGS. 1A, 1B and having a three-dimensional internal structure, can be thus manufactured at a time. Metal 128 described in FIG. 7A works as internal electrode 100 or external electrode 104, and also via-hole 144 becomes a via (not shown in FIGS. 1A, 2B). To be more specific, the third embodiment of the present invention proposes the method of manufacturing the electronic component, and the method comprises the steps of:
forming a groove or a hole in a given shape by using photosensitive resist colored with colorant;
forming a foundation-electrode at the groove or the hole;
depositing the wiring material, whose principal component is copper, on the foundation-electrode;
removing parts of the wiring material for flattening the wiring material;
repeating the foregoing steps several times; and
dividing the electronic components formed through the foregoing steps into pieces, i.e. discrete components.

As discussed above, the third embodiment proves that the use of colored photosensitive resin as resin pattern 124, uncured resin 140, and cured resin pattern 142 allows manufacturing a predetermined electronic component without using a substrate which has been one of structural elements of conventional electronic components. A lower profiled electronic component is thus obtainable, and the use of photosensitive resin colored at its resin section allows improving recognition of the components when they are mounted.

Advantages of the electronic component manufactured by using colored photosensitive resin are further detailed hereinafter. In the situation where miniaturized electronic components are commonly used, the photosensitive resin tends to remain at the bottom of via-hole 144 as described in FIG. 8: when metal 128 supposed to work as the electrical wiring is connected to metal 1282 filled into via-hole 144 supposed to work as a via. This remainder has adversely affected the characteristics of the products.

The problem of the remaining photosensitive resin at the bottom of via-hole 144 is described hereinafter. Assume that the electronic component in accordance with this third embodiment is a coil component, and then the coil has desirably a higher Q value, which is one of the coil characteristics. To heighten the Q value, a resisting value of the coil needs to be lowered. The resisting value of internal electrode 100 should be thus lowered in order to heighten the Q value, so that a thickness of the wiring should be increased. A thicker resin pattern 124 will do it. In the case of general photosensitive resin, an appropriate thickness is approx. 1 μm, and 3 μm at the highest. Because a resolution of the resin during the exposure is lowered as the thickness of the resin is increased. On the other hand, in the case of the electronic component proposed in this embodiment, the thickness is desirably thicker than the foregoing values, e.g. not less than 10 μm and not greater than 200 μm, more desirably not less than 15 μm and not greater than 100 μm, further desirably, not less than 20 μm and not greater than 60 μm. Exposure of such a thicker photosensitive resin needs a more intensive light source or a longer exposure time; however, reflected light in this case sometimes adversely affects an accuracy of processing the via-hole, although this problem has been neglected in conventional art.

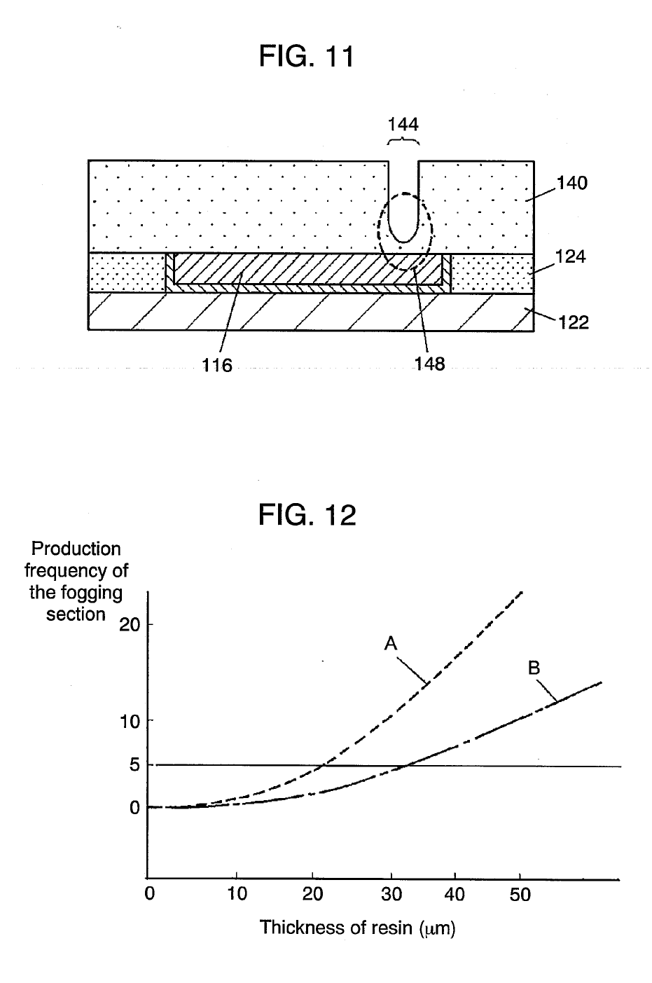

Next, a problem of exposing the via-hole is described with reference to FIGS. 10 and 11, which are sectional views illustrating this problem. As shown in FIG. 10, light 134 is shot to the electronic component through mask 136 having light blocking section 138. Light 134 passes through uncured photosensitive resin 140, then reflects on the surface of metal 128 and becomes reflected light 146. FIG. 10 corresponds to FIG. 6 with reflected light 146 added thereto. In the case of the present invention, the surface of metal 128 is flattened by polishing or etching in order to heighten the high-frequency characteristics of the coil, so that reflected light 146 tends to occur as shown in FIG. 10. Uncured resin 140 under light blocking section 138 of mask 136 is exposed to this reflected light 146, so that the resin remains at the bottom of via-hole 144, namely, what is called “exposure fogging” is produced and left at the bottom.

FIG. 11 is a sectional view showing the residual resin remaining at the bottom of the via-hole, and fogging section 148 is illustrated therein. Fogging section 148 is formed by curing a part of photosensitive resin 140 with reflected light 146. What is called “fogging section” is similar to a technical term used in the photographic trade such as “antifoggant” or “antifogging agent”.

FIG. 11 shows a sectional view of a sample affected by reflected light 146. In FIG. 11, fogging section 148 is shown. The sample affected by reflected light 146 as shown in FIG. 10 tends to produce fogging section 148 at the bottom of via-hole 144 as shown in FIG. 11. Fogging section 148 is produced by exposing its part, which is supposed to be in trouble if it is exposed to light, i.e. uncured resin 140 under light blocking section 138 is cured in parts by reflected light 146. As a result, fogging section 148 formed of cured resin 142 tends to be produced at the bottom of via-hole 144. A mechanism of producing this fogging section 148 is similar to a phenomenon of greater tanning obtainable in winter rather than in summer, e.g. when someone enjoys the ski, the sun light reflected on snow surface causes the greater tanning.

Fogging section 148 adversely affects the electronic component in the following manner: As shown in FIG. 11, fogging section 148 affects an electrical connection at via-hole 144 so that the wiring resistor sometimes increases or possibly breaks the wiring. The production of fogging section 148 thus must be prevented as little as possible.

The inventors, first of all, vary the roughness of the surface of metal 128, thereby trying to reduce the reflected light. FIG. 12 shows an example of the result.

FIG. 12 shows a relation between an amount of the residual resin (production frequency of the fogging section) of the photosensitive resin and a thickness of the resin. The X axis represents the thickness (unit: μm) of resin and the Y axis represents a frequency of producing the fogging section. The production frequency of the fogging section is a relative value calculated by using test patterns having via-holes of different sizes, and is used for evaluating the residual resin. Experiments done by the inventors have found that the production frequency exceeding 5 (five) affects the electrical characteristics. Broken line A and alternate long and short dash line B in FIG. 12 represent differences in the roughness of the surface of metal 128 while metal 128 is made of copper of the same material but different in surface roughness. As shown in FIG. 12, in the case of surface roughness A and the thickness of the photosensitive resin over 20 μm, and in the case of surface roughness B and the thickness thereof over 30 μm, it is found that the production frequency of the fogging section sharply exceeds 5, and increases onward. This result proves that the variation in surface roughness is not useful for suppressing the production of fogging section. The photosensitive resin used in this experiment is slightly colored and available in the market.

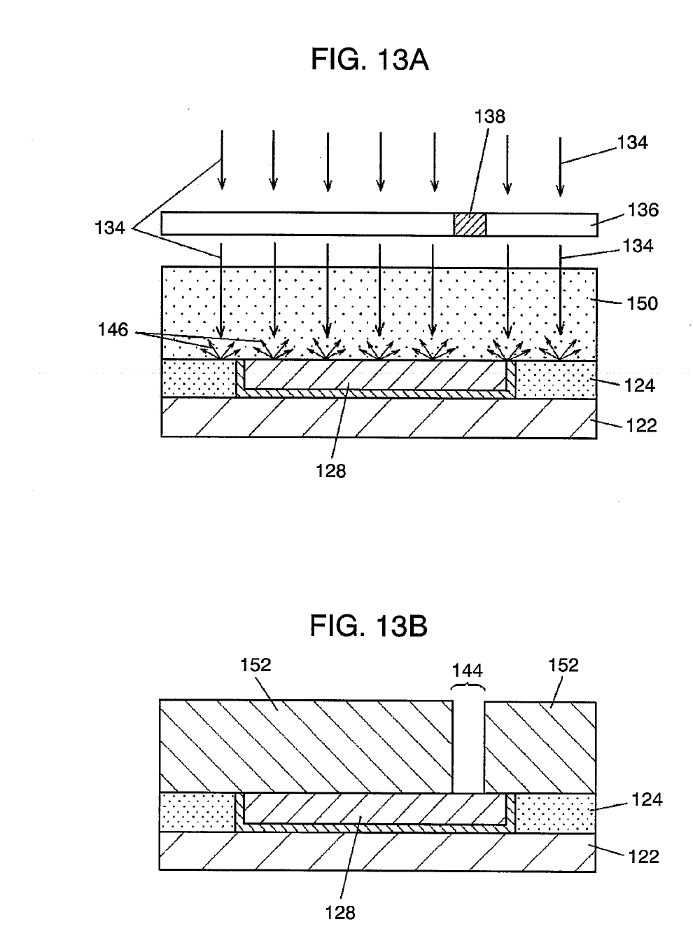

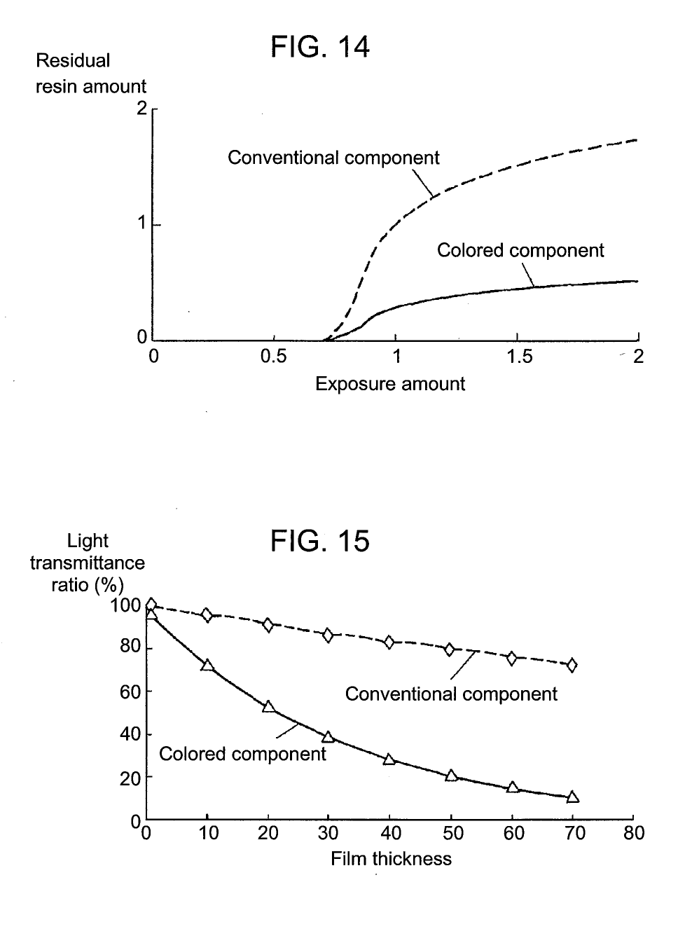

The inventors have then colored the photosensitive resin by adding dye, thereby developing a new photosensitive resin, and have succeeded in suppressing the influence of the reflected light. This result is described hereinafter with reference to FIG. 13A-FIG. 14.

FIG. 13A is a sectional view illustrating a theory that use of colored photosensitive resin reduces reflected light. As shown in FIG. 13A, uncured colored resin 150 is formed in the electronic component, resin 150 is in pre-exposure state of the newly developed colored photosensitive resin. As shown in FIG. 13B, cured and colored resin 152 is formed in the electronic component. Resin 152 is in post-exposure state of the newly developed colored photosensitive resin.

In FIG. 13A, uncured colored resin 150 is formed at a given thickness on resin pattern 124 and metal 128, and as shown in FIG. 13A, the use of the colored photosensitive resin here will reduce reflected light 146, for reflected light 146 is absorbed during its travel through the colored resin. As a result, as shown in FIG. 13B, the production of fogging section 148 is greatly suppressed at the bottom of via-hole 144 where cured colored resin 152 is formed. Meanwhile since the photosensitive resin is colored, the energy for the photosensitive resin to receive at the exposure to light can be somewhat affected. The relation between an exposure amount and an amount of the residual resin of the photosensitive resin is thus studied. FIG. 14 shows the result.

FIG. 14 shows an example of the relation between the exposure amount and the residual resin amount of the photosensitive resin. In FIG. 14, the X-axis represents an exposure amount (unit: any) and the Y-axis represents the residual resin amount (unit: any) which corresponds to the amount of the residual resin at fogging section 148. The inventors set an electronic component, having photosensitive resin slightly colored for identifying a pattern, as a conventional component, and set another electronic component, having colored photosensitive resin, as a colored component. The experiments done by the inventors have found that both of the components at an exposure amount not greater than 0.7 are peeled off their photosensitive resin due to lack of the exposure amount when they are developed. Assume that the optimum exposure amount to the conventional component is 1 (one), and the residual resin amount is 1 (one). Then each case is compared with each other. In the case of the colored resin used in the second embodiment, little amount of residual resin, i.e. 0.2-0.3, is produced at the exposure amount of 1 (one). This amount is as little as ¼-⅕ that of the conventional component, and it can be said that substantially no residual resin is produced. Next, the relation between the exposure amount and the residual resin mount is studied. When the exposure amount is increased from 1 onward, the conventional component further increases the residual resin amount as shown in FIG. 14; however, the colored component using the colored resin and used in the second embodiment increases the residual resin amount only little, and even when the exposure amount is doubled, the residual resin amount falls in the range not greater than 0.5. These results prove that excessive exposure produces little residual resin in the case of using the colored resin. On the other hand, in the case of using transparent resin, excessive exposure further increases the residual resin amount. As a result, the use of colored resin allows preventing the fogging in a stable manner.

The colorant for coloring the photosensitive resin desirably employs the colorant whose principal component is pigment or dye commercially available. It is also desirable to select the colorant whose principal component is carbon, metallic oxide, or non-magnetic material. Use of such a member as discussed above allows preventing the colorant from affecting the magnetic line of force produced by the coil. The foregoing colorants can be commercially available.

Photosensitive resin commercially available is slightly colored in red or another color, for transparent and colorless photosensitive resin cannot identify a pattern of the resin per se. However, a degree of coloring in this case is low enough not to get anti-reflection effect as shown in FIG. 14.

The electronic component having the following elements can be thus manufactured: a protecting section formed of at least the colored resin, a coil wiring formed within the protecting section and having a via connection, and an external electrode buried in the protecting section and yet parts thereof exposed. The use of the colored photosensitive resin allows accurately producing a via which tends to affect the characteristics of the electronic component, so that the electronic component with stable quality can be provided. Not to mention, the electronic component thus manufactured can prevent the built-in metal wiring from producing unnecessary reflected light caused by the lighting in mounting the component.

### Embodiment 4

An electronic component in accordance with the fourth embodiment is demonstrated hereinafter. The fourth embodiment touches on a method for optimizing the coloring of photosensitive resin in response to a shape of an electronic component.

Assume that outer dimensions of the electronic component are in accordance with 1005 size of JIS, i.e. 1.0 mm×0.5 mm×0.5 mm, which is extremely small in size. On the other hand, a thickness of the wiring should be increased to heighten the Q value. For instance, in the case of the third embodiment, in order to build a three-dimensional coil pattern into a smallest possible volume, the coil pattern needs such dimensions as wiring width: 10-100 μm, wiring thickness: 10-100 μm, via height: 10-100 μm. The foregoing coil pattern should be accurately built in.

The inventors have found in their experiments that when a via height is heightened, the via-hole tends more easily to be filled with resin or the photosensitive resin becomes fogging at a smaller via-hole diameter.

Next, a light transmittance of respective colored resin is optimized in response to thicknesses of the resin. One example is demonstrated with reference to FIG. 15, which shows a relation between a film thickness and its light transmittance, and touches on the colored resist the inventors have developed for themselves. FIG. 15 shows an instance of optimizing a degree of influence of the colored resin upon the residual resin. In FIG. 15, the X-axis represents a resin thickness (unit: μm), and the Y-axis represents a light transmittance, whose reference is 100% at thickness of 0 (zero). As shown in FIG. 15, the conventional component allows light to transmit approximately 95% at thickness of 10 μm, 90% at 20 μm, and 80% at 50 μm. This transmitted light becomes reflected light 146 shown in FIG. 10 and forms fogging section 148. On the other hand, the colored component allows light to transmit approximately 70% at the thickness of 10 μm, 55% at 20 μm, and 20% at 50 μm. The light transmittance is thus lowered. The colored component employs the colored resin which includes colorant added to the conventional resin, so that the difference in the graph shown in FIG. 15 is caused mainly by light absorption due to the colorant. FIG. 15 thus tells that at the same thickness, e.g. 50 μm, the use of the colored photosensitive resin allows suppressing reflected light 146 down to as low as 25%.

To be more specific, in the case of only one colored resin available, the resin desirably allows light to transmit in the range of one of 40% to 90% at the thickness of 10 μm, 20% to 80% at 20 μm, 10% to 70% at 30 μm, 5% to 60% at 40 μm, or 1% to 40% at 60 μm. If the light transmittance is lower than the foregoing ranges, this case sometimes affects an exposure time of an exposure machine. If the light transmittance is higher than the foregoing ranges, the case sometimes affects anti-reflected light effect. The resin falling within the foregoing ranges can deal with any case at the thickness range of 10 μm-60 μm.

Some products require a smaller via-hole, and such a case needs to further regulate the reflected light. To deal with this case, it is desirable to prepare a plurality of colored resins having different light transmittance in response to a size of via-hole, a height of the via or a height of the resin. For instance, it is desirable to use the resins which allow light to transmit in the range of 20% to 70% at the thickness of 10 μm, 20 μm, and 40 μm. It is more desirable that the range be 30% to 60%. In other words, the exposure time becomes more easily optimized at a narrower range of the light transmittance. As discussed above, in the case of maintaining the same light transmittance with various resin thicknesses, a degree of coloring lowers at a greater thickness of the resin, in other words, the color becomes paler. The degree of coloring becomes higher at a smaller thickness of the resin, namely, the color becomes deeper. As a result, color shading appears on the finished product as shown in FIG. 1, i.e. respective layers have different color tones. Use of different resins in response to the optimum design value of the coil wiring thus allows the electronic component to be further sophisticated.

Not to mention, as long as the resin, which protects the wiring, is colored at a certain degree over a given level, it can prevent unnecessary reflected light or irregular reflection in shooting light to the product.

### Embodiment 5

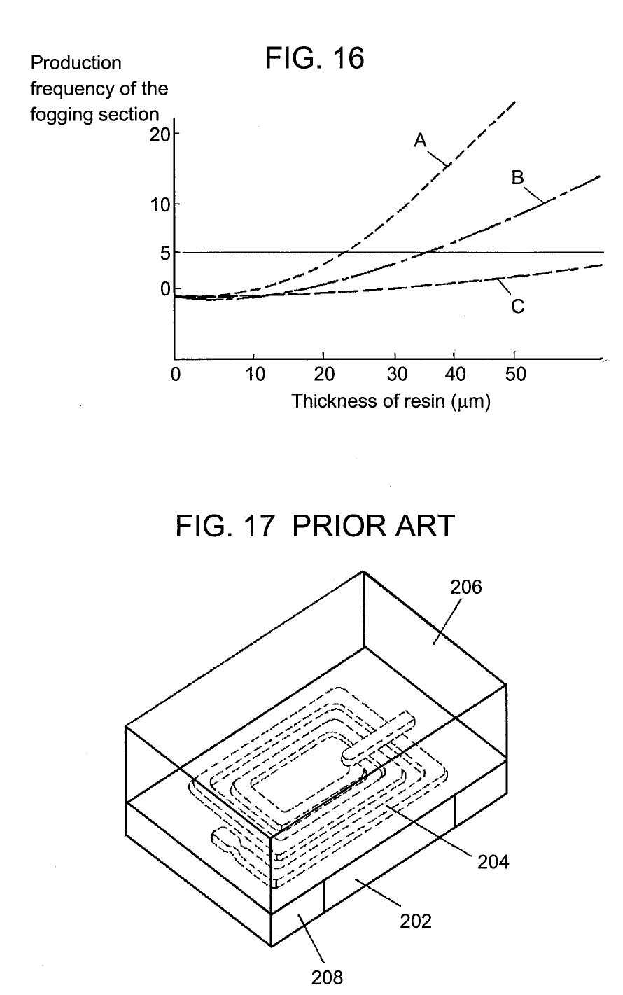

Embodiment 5 is demonstrated hereinafter, and it details the amount of residual resin and the thickness of resin. FIG. 16 illustrates the relation between the frequency of fogging production and the amount of exposure. In FIG. 16, the residual resin amount is evaluated by the frequency of fogging production. Both of broken line A and alternate long and short dash line B represent the typical photosensitive resin commercially available, which resin corresponds to the conventional component. Broken line C represents the colored photosensitive resin used in the fourth embodiment, which resin corresponds to the colored component. FIG. 16 tells that a thickness of general photosensitive resin (used in the conventional components) over 10 μm or 20 μm invites a sharp increase of the fogging production, namely, the residual resin amount sharply increases. This phenomenon is caused by the complicated internal structure of the electronic component of the present invention. To be more specific, not only the light reflected on the metal just below the photosensitive resin, but also the lights reflected on the wirings adjacent to or under the resin contribute to the frequency of fogging production in a complicated manner. In the case of the electronic component of the present invention, among others, the photosensitive resin is laminated in several layers or several tens of layers as a kind of permanent resin. Therefore the use of the conventional photosensitive resin sometimes invites an increase in the frequency of fogging production as the number of layers increases although the fogging production frequency is kept at a low level when a small number of layers is available. On the other hand, as shown in FIG. 16, the use of the colored component eliminates the influence of the light reflected on the plural wirings built in the lower section of the electronic component. Because the insulating layer formed in the lower section employs the colored layer, and the light is absorbed by this colored resin.

In conclusion, since the colored component employs the colored resin, accurate exposure can be carried out or a via-hole can be accurately formed regardless of the number of layers. As a result, the wiring resistance of the electronic component can be reduced, and on top of that, the coil characteristics can be improved.

The electronic component preferably includes at least a protecting section formed of colored resin; a coil wiring formed within the protecting section and having a via connection; and external electrodes buried in the protecting section while parts of the external electrodes are exposed. Layering two or more than two layers of the color resin allows forming the coil wiring in a three-dimensional structure internally. The electronic component can include a protecting section formed by layering a plurality of colored resins as shown in FIG. 1, a coil wiring formed within the protecting section and having a via connection; and external electrodes buried in the protecting section while parts of the external electrodes are exposed. This structure improves the anti-reflection function and increases the accuracy of forming via-hole 144.

The colored resin can be a colored photosensitive resin which is colored by the colorant whose principal component is pigment or dye. The commercially available photosensitive resin is thus colored with the colorant, thereby forming the colored resin of the present invention. Pigment or dye commercially available can be thus used for such a coloring application.

The colored resin can be a colored photosensitive resin which is colored with a colorant whose principal component is carbon, metal, metallic oxide, or non-magnetic material, thereby forming the colored resin of the present invention by using the photosensitive resin commercially available. For instance, carbon (carbon black, graphite, carbon nano-fiber, carbon nano-tube, activated carbon) can be an inexpensive and excellent member to be colored. Use of oxide or non-magnetic material as a colorant produces no influence on the magnetic field produced by the coil. Positive use of pigment, carbon, metallic oxide, non-magnetic material, or dye as a colorant allows stabilizing the coil characteristics.

Carbon, metallic oxide, non-magnetic material, pigment or dye used as a colorant preferably has an average particle diameter ranging from 1 nm to 10 μm. A material having an average particle diameter smaller than 1 nm sometimes encounters difficulty in dispersion into photosensitive resin material. A material having an average particle diameter over 10 μm will affect forming a fine pattern.

An additive amount of pigment, carbon, metallic oxide, non-magnetic material, or dye preferably falls within the range of 0.01 wt to 2 wt % with respect to the photosensitive resin. If an additive amount of those materials is less than 0.01 wt %, a degree of coloring becomes so low that expected anti-reflection effect sometimes cannot be obtained. If the additive amount exceeds 2 wt %, the exposure characteristics or physical properties of the photosensitive resin are sometimes affected.

The colorant is preferably selected such that a light transmittance in a photosensitive wavelength or in visible light wavelength of photosensitive resin falls within the range of 40%-90% at the resin thickness of 10 μm, 20%-80% at 20 μm, 10%-70% at 30 μm, 5%-60% at 40 μm or 1%-40% at 60 μm. The photosensitive wavelength is a wavelength that affects the curing reaction of the photosensitive resin. The light transmittance within the foregoing ranges obtains an anti-fogging effect as long as the resin thickness falls within the range of 10 μm to 60 μm.

The via preferably has a height ranging from 5 μm to 100 μm for preventing the fogging, and more preferably, it falls within the range of 10 μm-70 μm, still more preferably, it falls within the range of 20 μm-50 μm. If the height is less than 5 μm, it is sometimes difficult for the colored resin to obtain the anti-fogging effect. If the height of the via is too high, the number of turns of the coil is limited because the coil should be built within the component having a limited height.

The wiring is preferably made of copper because the wiring formed of metal whose principal component is copper can suppress a wiring resistance. In the case of coil component in particular, a thickness of the wiring is preferably increased for lowering the wiring resistance. For instance, the thickness preferably falls within the range of 10 μm-50 μm. In such a case, the conductivity of foundation-electrode 126 is used, and the wiring made of principally copper is preferably formed by plating. This method allows achieving a cost greatly lower than the vacuum method.

The cross section of the coil wiring is substantially a quadrangle, and at least three faces of the coil wiring form multi-layers made of the same metal or different metals, so that the wiring resistance can be minimized in a limited volume. Foundation-electrode 126 is formed on at least three faces of the coil wiring, so that the accurate and steady wiring can be formed by using the photosensitive resin and a plating technique.

### INDUSTRIAL APPLICABILITY

An electronic component of the present invention and a method for manufacturing the same electronic component allow reducing a height of the electronic component, downsizing and increasing handleability of the electronic component, so that they are useful for downsizing and sophisticating a variety of electronic devices.

1. An electronic component comprising:
a protecting section including colorant and photosensitive resin;
a coil wiring formed in the protecting section and having a via connection; and
an external electrode buried in the protecting section and exposed partially.

2. The electronic component of claim 1, wherein the colorant is made of one of pigment, carbon, metallic oxide, non-magnetic material, and dye.

3. The electronic component of claim 2, wherein one of the carbon, the metallic oxide, the non-magnetic material, the pigment, and the dye has an average particle diameter falling within a range of not smaller than 1 nm and not greater than 10 μm.

4. The electronic component of claim 1, wherein an additive amount of the colorant, whose principal component is one of pigment, carbon, metallic oxide, non-magnetic material, and dye, falls within a range of not smaller than 0.01 wt % and not greater than 2 wt % with respect to the photosensitive resin.

5. The electronic component of claim 1, wherein the colorant has a light transmittance with respect to a photosensitive wavelength of the photosensitive resin, the light transmittance falling within one of ranges of:
not less than 40% and not greater than 90% at a resin thickness of 10 μm;
not less than 20% and not greater than 80% at a resin thickness of 20 μm;
not less than 10% and not greater than 70% at a resin thickness of 30 μm;
not less than 5% and not greater than 60% at a resin thickness of 40 μm; and
not less than 1% and not greater than 40% at a resin thickness of 60 μm.

6. The electronic component of claim 1, wherein a height of a via forming the via connection is not less than 5 μm and not greater than 100 μm.

7. The electronic component of claim 1, wherein the coil wiring is made of principally copper.

8. The electronic component of claim 1, wherein a cross section of the coil wiring forms substantially a quadrangle, and at least three faces of the quadrangle form a multi-layer formed of an identical metal or different metals.

9. A method for manufacturing an electronic component comprising:
forming a groove or a hole in a given shape by using photosensitive resist colored by colorant;
forming a foundation-electrode at the groove or the hole;
depositing wiring material, whose principal component is copper, on the foundation-electrode;
removing a part of the wiring material for flattening the wiring material;
repeating the steps several times; and then
dividing the wiring material into pieces.

10. The method for manufacturing an electronic component of claim 9, wherein a wiring made by depositing the wiring material is formed through an electric plating method by using electrical conductivity of the foundation-electrode.

11. The method for manufacturing an electronic component of claim 9, wherein a part of the foundation-electrode is removed when a part of the wiring material is removed.
